(19) United States
(12) Patent Application Publication
(10) Pub. No.: US 2025/0386523 A1
(43) Pub. Date: Dec. 18, 2025

(54) TUNNELING BARRIER RESISTOR AND METHODS FOR FORMING THE SAME

(71) Applicant: SANDISK TECHNOLOGIES LLC, ADDISON, TX (US)

(72) Inventors: Wonjoon JUNG, San Jose, CA (US); Michael GROBIS, Campbell, CA (US); Lei WAN, San Jose, CA (US); Hans RICHTER, Palo Alto, CA (US); James REINER, Palo Alto, CA (US); Tiffany SANTOS, Palo Alto, CA (US)

(21) Appl. No.: 18/774,112

(22) Filed: Jul. 16, 2024

Related U.S. Application Data
(60) Provisional application No. 63/660,839, filed on Jun. 17, 2024.

(51) Int. Cl. H01C 1/14; H10B 61/00; H10B 63/00; H10N 80/00

(52) U.S. Cl. CPC H10D 1/47; H01C 1/14; H10B 61/00; H10B 63/00; H10N 80/00

(57) ABSTRACT

A tunneling barrier resistor includes a first electrode layer containing a first nonmagnetic iron-group-containing alloy layer which includes a first refractory metal, a second electrode layer containing a second nonmagnetic iron-group-containing alloy layer which includes a second refractory metal, and a first tunneling barrier dielectric layer located between the first electrode layer and the second electrode layer.

### FIELD

The present disclosure relates generally to the field of semiconductor devices and specifically to a tunneling barrier resistor, a device incorporating the same, and methods of forming the same.

### BACKGROUND

Memory devices include oxide-based resistive random access memory (ReRAM) devices, magnetoresistive random access memory (MRAM) devices which may include ovonic threshold switch (OTS) selectors for each MRAM memory cell, and OTS offset voltage memory devices. These memory devices suffer from narrow read voltage windows and read disturb during the read operation.

### SUMMARY

According to an aspect of the present disclosure, a device comprises a tunneling barrier resistor. The tunneling barrier resistor includes a first electrode layer containing a first nonmagnetic iron-group-containing alloy layer which includes a first refractory metal, a second electrode layer containing a second nonmagnetic iron-group-containing alloy layer which includes a second refractory metal, and a first tunneling barrier dielectric layer located between the first electrode layer and the second electrode layer.

According to another aspect of the present disclosure, a method of forming a tunneling barrier resistor comprises depositing a first refractory metal layer; depositing a first amorphous iron-group-containing alloy layer on the first refractory metal layer to form a first electrode layer comprising a first nonmagnetic iron-group-containing alloy layer which includes the first refractory metal; depositing a first tunneling barrier dielectric layer on the first electrode layer; depositing a second amorphous iron-group-containing alloy layer on the first tunneling barrier dielectric layer; and depositing a second refractory metal layer on the second amorphous iron-group-containing alloy layer to form a second electrode layer comprising a second nonmagnetic iron-group-containing alloy layer which includes the second refractory metal.

### BRIEF DESCRIPTION OF THE DRAWINGS

FIG. 1 is a schematic diagram of a series connection of a tunneling barrier resistor and a negative differential resistance (NDR) element according to an embodiment of the present disclosure.

FIG. 2 is a schematic diagram of a circuit including a series connection of a tunneling barrier resistor and a negative differential resistance (NDR) element according to an embodiment of the present disclosure.

FIG. 3 is a graph illustrating the effect of a resistance of a tunneling barrier resistor on a read voltage window of an OTS offset voltage memory cell.

FIGS. 4A and 4B are vertical cross-sectional views of configurations of a first exemplary device according to an embodiment of the present disclosure.

FIGS. 5A and 5B are vertical cross-sectional views of configurations of a second exemplary device according to an embodiment of the present disclosure.

FIGS. 6A and 6B are vertical cross-sectional views of configurations of a third exemplary device according to an embodiment of the present disclosure.

FIGS. 7A and 7B are vertical cross-sectional views of configurations of a fourth exemplary device according to an embodiment of the present disclosure.

FIGS. 8A and 8B are vertical cross-sectional views of configurations of a fifth exemplary device according to an embodiment of the present disclosure.

FIGS. 9A and 9B are vertical cross-sectional views of configurations of a sixth exemplary device according to an embodiment of the present disclosure.

### DETAILED DESCRIPTION

Embodiments of the present disclosure are directed to a tunneling barrier resistor, a device incorporating the same, and methods of forming the same.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

A “negative differential resistance element” or an NDR element refers to a component or material in an electronic device exhibiting the characteristic where an increase in the applied voltage leads to a decrease in the electrical current through the element, over a specific range of operating conditions. In other words, dI/dV<0 for a voltage range for a negative differential resistance element. This phenomenon results in a region within the current-voltage (I-V) characteristics of the element where the differential resistance, defined as the derivative of the voltage with respect to the current, becomes negative.

A “tunneling barrier resistor” refers to an electronic component that exhibits resistance based on the tunneling effect through a thin insulating barrier located between two electrically conductive layers. The resistance level of this component is primarily governed by the thickness and material properties of the insulating barrier, which permits quantum tunneling of charge carriers between the conductive layers. This tunneling process allows for the controlled flow of current at a nano-scale, enabling the resistor to achieve very high resistance values with precise tunability. Thus, the tunneling barrier resistor operates by passing a current through the tunneling barrier resistor using quantum tunneling.

The set process in the oxide-based resistive random access memory (ReRAM) cells can induce a current runaway, severely compromising cell endurance by failing to limit the continual decrease in resistance with increasing current. Further, the minimum operating currents of threshold switching devices are affected by the level of local resistance, with higher resistance leading to reduced read currents and potentially compromising bit error rate (BER) performance. In ovonic threshold switch (OTS) offset voltage memory cells, lower read current levels are desirable for minimizing read disturb and maximizing the read window, respectively, to enhance BER performance. However, challenges arise when series resistors for controlling these currents are not closely integrated with the memory cell, leading to interference of stray capacitance from adjacent capacitors located in the memory device on memory cell operation.

According to an aspect of the present disclosure, a tunneling barrier resistor may be integrated with the negative differential resistance (NDR) element which either comprises a memory cell or is used as a selector of a memory cell to provide controlled resistance. For example, the tunneling barrier resistor may be integrated into a negative differential resistance (NDR) device or into a memory device having an NDR selector, facilitating the regulation of current and voltage characteristics and leading to the stable operation of the device. The compact tunneling barrier resistor having nanometer-scale thickness and ability to be stacked in series with various devices, provides a robust mechanism for enhancing the performance and endurance of the devices. The devices include NDR devices, such as radio frequency and microwave emitter devices, including spin torque oscillator (STO), impact ionization avalanche transit-time (IMPATT) diode, and Gunn diode NDR elements, high resistance memory elements, such as oxide based ReRAM, NDR memory devices, such as OTS offset voltage memory devices, and memory devices containing NDR selectors, such as OTS selectors for MRAM memory devices. This integration serves to mitigate potential deleterious effects, such as current runaway and to improve the overall reliability and efficiency of the devices.

The integration of a tunnel barrier resistor with a memory device or an NDR device allows for high resistances, precise control over resistance values, and stable performance over many cycles without degradation. The tunnel barrier may be electrically connected in series with the NDR device and/or the memory element described above to fine-tune the total resistance, leading to improvements in the device performance of the memory device or the NDR device. In one embodiment, the tunneling barrier resistor may be located adjacent to the NDR device and/or memory element, which allows quick stabilization of the NDR memory element or selector by mitigating parasitic capacitance effects. In a non-limiting example, the tunneling barrier resistor can comprise a tunneling barrier material layer such as magnesium oxide (MgO), silicon oxide (e.g., silicon dioxide), titanium oxide (e.g., titanium dioxide) or hafnium oxide (e.g., hafnium dioxide) layer. For example, the tunneling barrier material layer may comprise an amorphous MgO layer having a thickness of 0.5 to 1.5 nm. The tunneling barrier material layer may be located between two electrically conductive electrode layers (i.e., electrodes). The electrically conductive electrode layers may comprise thin, amorphous, mixed nonmagnetic metallic layers of cobalt iron boron (CoFeB) intermixed with a nonmagnetic metal, such as tungsten, tantalum and/or ruthenium. The electrically conductive electrode layers may have a thickness of 1 nm or less, such as 0.5 to 0.9 nm, and have a magnetic moment and magnetoresistance values close to zero. In this case, the tunnel barrier resistor exhibits no tunneling magnetoresistance effect. Such electrode layers provide high-quality interface formation with the tunneling barrier material layer, such as MgO, and controlled resistance values.

In one embodiment, a stack of tunnel barrier junction structures may be provided to improve breakdown performance and support higher voltage applications. Various embodiments of the present disclosure are now described with reference to accompanying drawings.

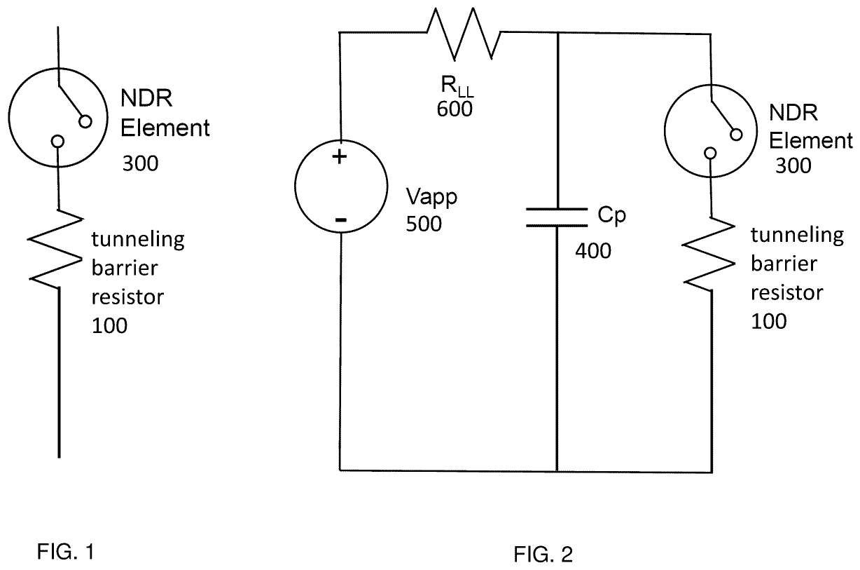

Referring to FIG. 1, a first exemplary circuit is illustrated, which includes a tunneling barrier resistor 100 of the embodiments of the present disclosure. The tunneling barrier resistor 100 is connected in series to a negative differential resistance (NDR) element 300. The NDR element 300 may comprise a spin torque oscillator (STO), an IMPATT diode or a Gunn diode. An STO is a spintronic device used in high-frequency applications, such as radio frequency and microwave band communication devices. STO devices may be used as a spin-diode rectifier, in wireless transmission and reception, in digital and analog modulators, in spectrum analyzers, and in neuromorphic computing. STO devices include magnetic tunnel junctions (MTJs) with CoFeB as the free layer. STO devices exhibit magnetic anisotropy and a tunneling magnetoresistance (TMR) of over 70%.

Referring to FIG. 2, a second exemplary circuit is illustrated, which includes the tunneling barrier resistor 100 of the embodiments of the present disclosure. A capacitor 400 is connected in parallel with the above described series connection of the tunneling barrier resistor 100 and the negative differential resistance (NDR) element 300 to a power source 500, such as a voltage source. The power source 500 may be connected in series to resistive load RLL 600. The tunneling barrier resistor 100 in this circuit may be used to minimize the impact of stray capacitance from the capacitor 400 on the performance of the NDR element 300, particularly during high-speed switching operations.

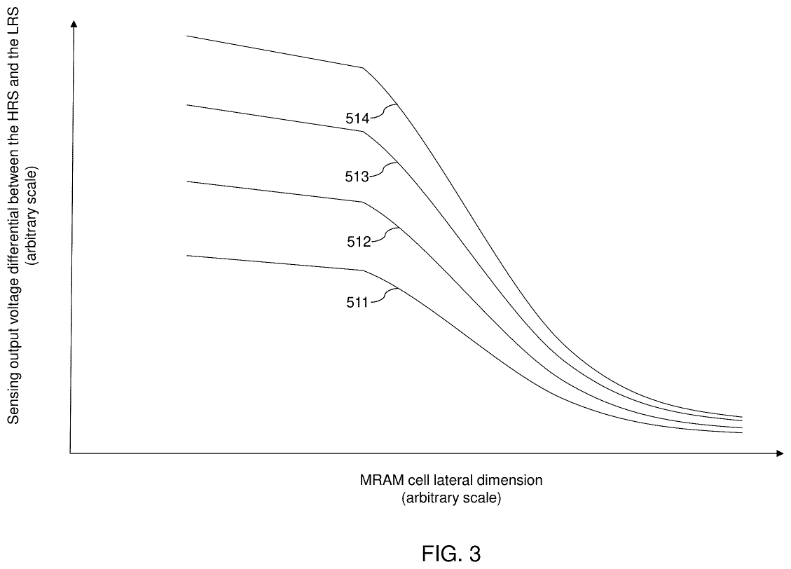

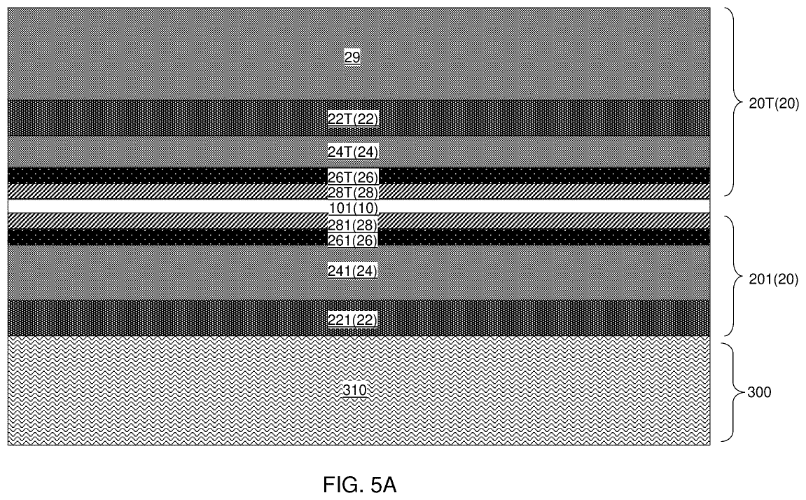

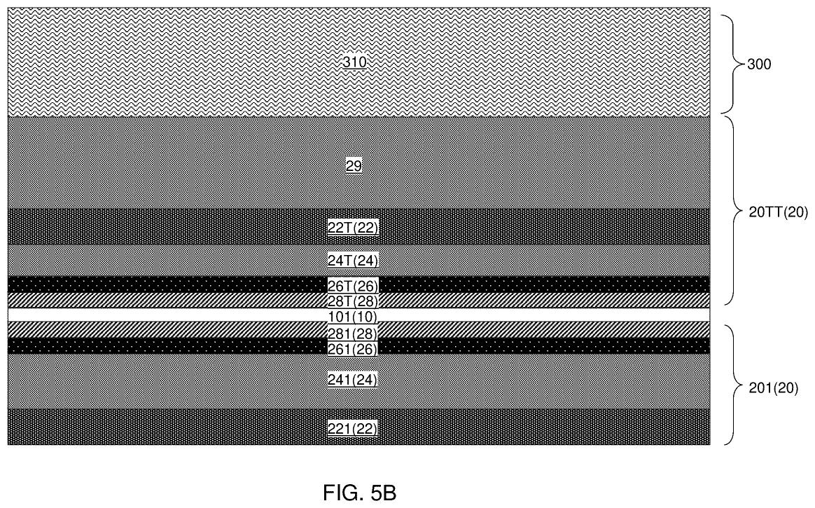

FIG. 3 is a graph schematically illustrating the effect of the resistance of a tunneling barrier layer on the sensing output voltage differential in a sense circuit. The test data was generated for various series connections of an OTS-only offset voltage memory cell and four different MRAM memory cells which function as a tunneling barrier resistor. Curve 511 corresponds to the lowest resistance MRAM cell located in series with the OTS memory cell. Curve 512 corresponds to the next lowest resistance MRAM cell located in series with the OTS memory cell. Curve 513 corresponds to the next lowest resistance MRAM cell located in series with the OTS memory cell. Curve 514 corresponds to the highest resistance MRAM cell located in series with the OTS memory cell. As shown in FIG. 5, the higher the resistance of the MRAM cell which functions as the tunneling barrier resistor, the higher the measured voltage difference between the low resistance state (LRS) and the high resistance state (HRS) of the OTS memory cell. Thus, a tunneling barrier resistor increases the read window (i.e., the measured voltage difference between the LRS and the HRS) of the OTS memory cell.

In subsequent embodiments described below, the tunneling barrier resistor 100 includes nonmagnetic electrodes 20 rather than the ferromagnetic CoFeB electrodes of the MRAM cells used in the example of FIG. 5 to avoid a series connection of two different types of memory cells. However, in an alternative embodiment, ferromagnetic electrodes 20 may be used in the tunneling barrier resistor 100 of the embodiments described below.

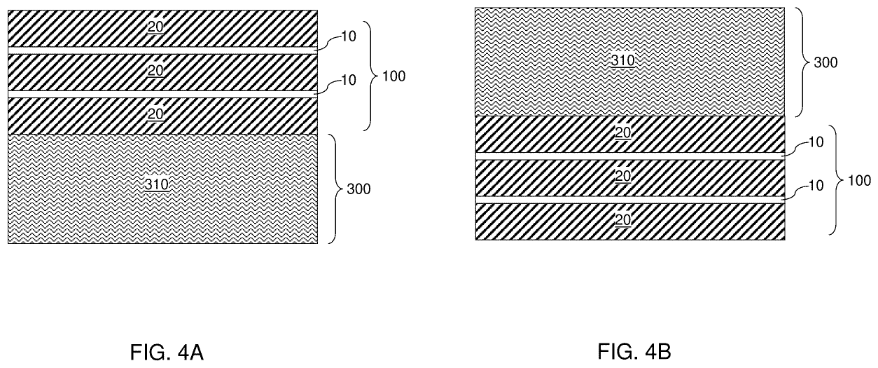

Referring to FIGS. 4A and 4B, configurations of a first exemplary device of the first embodiment are illustrated. The first exemplary device comprises a tunneling barrier resistor 100 including at least two metallic electrodes 20 and at least one tunneling barrier dielectric layer 10. The tunneling barrier resistor 100 may be formed in a series connection with a non-Ohmic device component 300, which may comprise the negative differential resistance element 300 described above. In one embodiment, the non-Ohmic device component 300 comprises at least one material portion 310 that may be patterned in the same pattern as the pattern of the tunneling barrier resistor 100. The at least one material portion 310 may comprise a magnetic tunnel junction of a STO device, an IMPATT or Gunn diode, OTS offset voltage memory cell, an OTS selector of a MRAM memory cell, or an a ReRAM memory cell comprising a metal oxide ReRAM layer.

Generally, the non-Ohmic device component 300 may be formed underneath the tunneling barrier resistor 100, or above the tunneling barrier resistor 100. If the non-Ohmic device component 300 comprises a set of at least one material portion 310 that may be patterned in the same pattern as the pattern of the tunneling barrier resistor 100, the material of the non-Ohmic device component 300 may be deposited prior to deposition of the material layers of the tunneling barrier resistor 100 as illustrated in FIG. 4A, or may be deposited after deposition of the material layers of the tunneling barrier resistor 100 as illustrated in FIG. 4B.

Subsequently, a patterned etch mask layer (which may be a patterned photoresist layer or patterned hardmask layer) can be formed above the combination of the set of at least one material portion 310 for formation of the non-Ohmic device component 300 and the material layers of the tunneling barrier resistor 100. A patterning process can be performed to pattern at least the upper portion of the combination employing the patterned etch mask layer. At least one reactive ion etch process and/or at least one ion beam etch process may be employed to pattern the combination into a vertical stack. In some embodiments, a vertical stack of a non-Ohmic device component 300 and a tunneling barrier resistor 100 may have a straight vertical or tapered sidewall that extends from the bottommost surface of the vertical stack to the topmost surface of the vertical stack. In some other embodiments, a spacer, such as a tubular dielectric spacer, may be formed on the sidewall of the patterned non-Ohmic device component 300 and/or the tunneling barrier resistor 100 stack.

Generally, the number of the tunneling barrier dielectric layers 10 within the tunneling barrier resistor 100 may be 1, or may be a number greater than 1. The number of the metallic electrodes 20 may be 2, or may be a number greater than 2. In one embodiment, the number of the metallic electrodes 20 may be greater than the number of the tunneling barrier dielectric layers 10 by 1. The metallic electrodes 20 within the first exemplary structure illustrated in FIGS. 4A and 4B may be formed with any configuration illustrated in FIGS. 5A-9B. As such, the configurations of the first exemplary structure are representations of the general configuration of the devices of various specific embodiments of present disclosure described with reference to FIGS. 5A-9B.

Referring to FIGS. 5A and 5B, configurations of a second exemplary structure according to a second embodiment are illustrated. The tunneling barrier resistor 100 may comprise a first metallic electrode 201 and a terminal metallic electrode 20T (which is a second metallic electrode). A tunneling barrier dielectric layer 10 (which is also referred to a first tunneling barrier dielectric layer 101) is located between the first metallic electrode 201 and the terminal metallic electrode 20T. Each of the first metallic electrode 201 and the terminal metallic electrode 20T may optionally comprise a respective set of at least one metallic spacer (22, 24), which may comprise, for example, a diffusion barrier metallic spacer 22 and a high-conductivity metallic spacer 24. For example, the first metallic electrode 201 may comprise a first diffusion barrier metallic spacer 221 and a first high-conductivity metallic spacer 241 located between the NDR element 300 and the tunneling barrier dielectric layer 10. The terminal metallic electrode 20T may comprise a terminal high-conductivity metallic spacer 24T and a terminal diffusion barrier metallic spacer 22T overlying the tunneling barrier dielectric layer 10.

The diffusion barrier metallic spacers 22 comprise or consist essentially of a transition metal that can function as an effective diffusion barrier material. In one embodiment, the diffusion barrier metallic spacers 22 comprise or consist essentially of a refractory metal such as Ta, W, Cr, Mo and/or Hf. The thickness of each diffusion barrier metallic spacer 22 may be in a range from 1.5 nm to 3 nm, although lesser and greater thicknesses may also be employed.

The high-conductivity metallic spacers 24 comprise or consist essentially of a noble metal. For example, the high-conductivity metallic spacers 24 may comprise, and/or may consist essentially of, Ru, Rh, Ir and/or Pd. In an illustrative example, the diffusion barrier metallic spacers 22 may consist essentially of Ta, and the high-conductivity metallic spacers 24 may consist essentially of Ru. The thickness of each high-conductivity metallic spacer 24 may be in a range from 1 nm to 5 nm, such as from 2 nm to 4 nm, although lesser and greater thicknesses may also be employed. The materials of the diffusion barrier metallic spacers 22 and the high-conductivity metallic spacers 24 may be deposited, for example, by physical vapor deposition.

Optionally, a capping metal layer 29 may be provided on the top surface of the at least one terminal metallic spacer (24T, 22T) and/or on the bottom surface of the at least one first metallic spacer (221, 241). If present, each capping metal layer 29 may comprise a noble metal layer. For example, each capping metal layer 29 may comprise, and/or may consist essentially of, Ru, Rh, Ir or Pd. The thickness of the capping metal layer 29 may be in range from 3 nm to 10 nm, such as 4 nm to 6 nm although lesser and greater thicknesses may also be employed.

The tunneling barrier resistor 100 further comprises a layer stack including in order, a first metal layer 261 comprising a first transition metal element, a first nonmagnetic iron-group-containing alloy layer 281, a first tunneling barrier dielectric layer 101, a terminal nonmagnetic iron-group-containing alloy layer 28T, and a terminal metal layer 26T comprising a terminal transition metal element. As used herein, iron group elements refer to Fe, Co, and/or Ni. An iron-group-containing alloy refers to an alloy including at least one iron group element as a primary component. If at least one first metallic spacer (221, 241) and at least one terminal metallic spacer (24T, 22T) are employed, the layer stack may be provided between the at least one first metallic spacer (221, 241) and at least one terminal metallic spacer (24T, 22T).

The first tunneling barrier dielectric layer 101 comprises a tunneling dielectric material such as magnesium oxide, a spinel material (such as magnesium aluminum oxide), silicon oxide, hafnium oxide, titanium oxide, or another transition metal oxide. The first tunneling barrier dielectric layer 101 may be deposited in an amorphous phase, for example, by atomic layer deposition, physical vapor deposition, or chemical vapor deposition. The thickness of the first tunneling barrier dielectric layer 101 may be in a range from 0.5 nm to 1.5 nm, such as from 0.6 nm to 1.2 nm, although lesser and greater thicknesses may also be employed.

In one embodiment, the first metal layer 261 and the alloy layer 281 comprise ultra-thin, discontinuous layers which intermix after deposition to form a first amorphous, nonmagnetic mixed metallic first electrode layer 271. The first metal layer 261 and the alloy layer 281 may each have a thickness of 1 nm or less, and the first electrode layer 27 has a thickness of 1.5 nm or less, such as 1 nm or less. In one embodiment, the terminal metal layer 26T and the terminal alloy layer 28T comprise ultra-thin, discontinuous layers which intermix after deposition to form an amorphous, nonmagnetic mixed metallic termina electrode layer 27T. The first metal layer 261 and the alloy layer 281 may each have a thickness of 1 nm or less, and the terminal electrode layer 27T has a thickness of 1.5 nm or less, such as 1 nm or less. Thus, the tunnelling barrier dielectric layer 101 (e.g., 10) is located between and contacts the respective electrode layers 27 (e.g., 271 and 27T).

The as deposited first alloy layer 281 comprises a first amorphous iron-group-containing alloy layer and the as deposited terminal alloy layer 28T comprises a terminal amorphous iron-group-containing alloy layer. Each as deposited layer (281, 28T) comprises and/or consists essentially of a respective amorphous material, which comprises at least one iron group element at an atomic percentage of at least 30%, and preferably at least 50%, and even more preferably at least 65%. In one embodiment, at least one of the first amorphous iron-group-containing alloy layer 281 and the terminal amorphous iron-group-containing alloy layer 28T may comprise and/or consist essentially of an amorphous, nonmagnetic iron-cobalt alloy which may optionally include boron atoms. Thus, the first and terminal alloy layers (281, 28T) may comprise CoFe or CoFeB alloy layers. The thickness of each of the first amorphous iron-group-containing alloy layer and the terminal amorphous iron-group-containing alloy layer may be in a range from 0.3 nm to 1 nm, such as from 0.5 nm to 0.8 nm, although lesser and greater thicknesses may also be employed.

The first metal layer 261 and the terminal metal layer 26T may each comprise a refractory metal layer, such as Ta, W, Cr, Mo and/or Hf. The thickness of each of these layers may be in a range from 0.2 nm to 1 nm, such as from 0.3 nm to 0.5 nm, although lesser and greater thicknesses may also be employed. In one embodiment, the first metal layer 261 has a thickness less than the thickness of the first nonmagnetic iron-group-containing alloy layer 281, and the terminal metal layer 26T has a thickness less than the thickness of the terminal nonmagnetic iron-group-containing alloy layer 28T.

According to an aspect of the present disclosure, layers 261 and 281 intermix either during deposition or during a subsequent anneal to form the first electrode layer 271. Likewise, layers 26T and 28T intermix either during deposition or during a subsequent anneal to form the terminal electrode layer 27T. Since the electrode layers 27 are very thin, they may be discontinuous or continuous. They may have an amorphous structure or they may be crystallized into a polycrystalline structure during a subsequent anneal. However, since the electrode layers 27 are very thin (e.g., have a thickness of 1 nm or less) they may comprise one to three monolayers, in which the difference between the amorphous and crystalline state is difficult to detect. The addition of the refractory metal, such as tungsten from the metal layers 261 and 26T into the electrode layers 27 renders the electrode layers nonmagnetic irrespective of their crystalline state. Thus, the electrode layers 27 may comprise a mixed layer or an alloy layer including cobalt, iron, boron and a refractory metal, such as tungsten.

In some embodiments, materials of the at least one metallic spacer (22, 24) may collaterally diffuse into the electrode layers 27 during deposition or during a subsequent anneal process. For example, some metal atoms from the first diffusion barrier metallic spacer 221 and/or the first high-conductivity metallic spacer 241 may be present within the first electrode layer 271, and some metal atoms from the terminal diffusion barrier metallic spacer 22T and/or the terminal high-conductivity metallic spacer 24T may be present within the terminal electrode layer 27T.

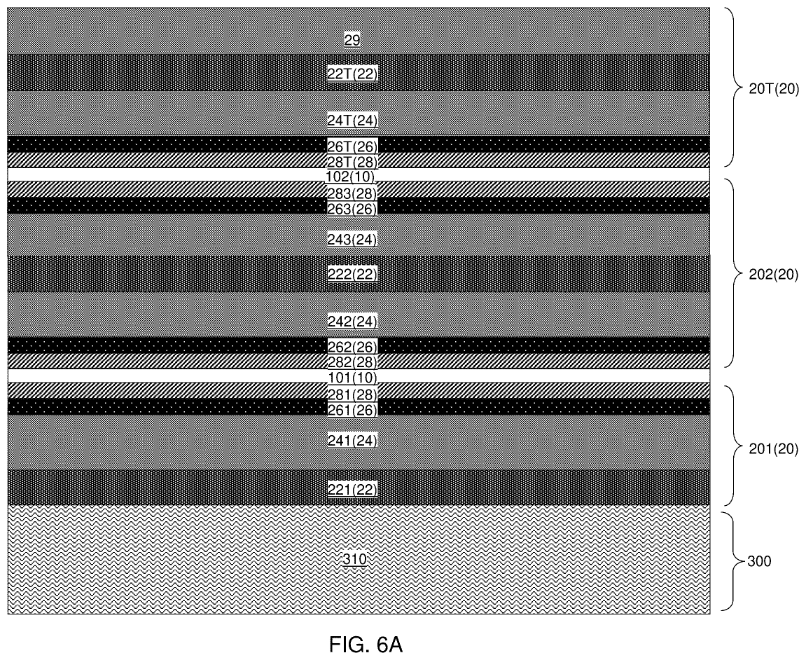

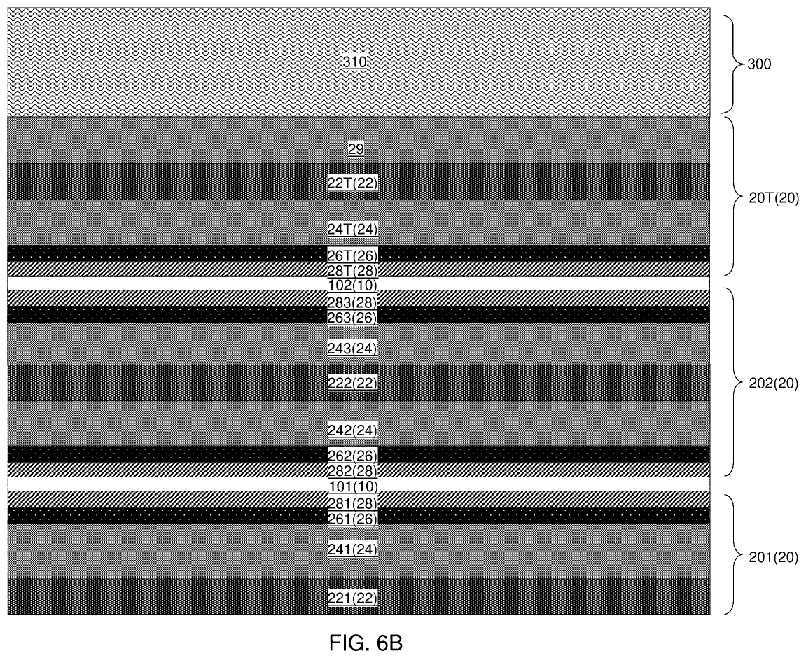

Referring to FIGS. 6A and 6B, configurations of a third exemplary structures according to the third embodiment are illustrated. The third exemplary structure may be derived from the second exemplary structure by inserting a second metallic electrode 202 and a second tunneling barrier dielectric layer 102 between the first tunneling barrier dielectric layer 101 and the terminal nonmagnetic iron-group-containing alloy layer 28T. The second tunneling barrier dielectric layer 102 may have any material composition that may be employed for the first tunneling barrier dielectric layer 101, and may have any thickness that may be employed for the first tunneling barrier dielectric layer 101. The material composition and/or the thickness of the second tunneling barrier dielectric layer 102 may be the same as or may be different from the material composition and/or the thickness of the first tunneling barrier dielectric layer 101, respectively.

The second metallic electrode 202 may comprise, from bottom to top, a second nonmagnetic iron-group-containing alloy layer 282, a second metal layer 262, a second high-conductivity metallic spacer 242, a second diffusion barrier metallic spacer 222, a third high-conductivity metallic spacer 243, a third metal layer 263, and a third nonmagnetic iron-group-containing alloy layer 283.

Generally, the second nonmagnetic iron-group-containing alloy layer 282 and the third nonmagnetic iron-group-containing alloy layer 283 may independently have the same material composition and the same thickness range as any material layer that may be employed for the first nonmagnetic iron-group-containing alloy layer 281 or the terminal nonmagnetic iron-group-containing alloy layer 28T. The second metal layer 262 and the third metal layer 263 may independently have the same material composition and the same thickness range as any material layer that may be employed for the first metal layer 261 or the terminal metal layer 26T. The second high-conductivity metallic spacer 242 and the third high-conductivity metallic spacer 243 may independently have the same material composition and the same thickness range as any material layer that may be employed for the first high-conductivity metallic spacer 241 or the terminal high-conductivity metallic spacer 24T. The second diffusion barrier metallic spacer 222 may have the same material composition and the same thickness range as any material layer that may be employed for the first diffusion barrier metallic spacer 221 or the terminal diffusion barrier metallic spacer 22T.

The compositional profile of the second nonmagnetic iron-group-containing alloy layer 282 may have the characteristics of the compositional profile of the terminal nonmagnetic iron-group-containing alloy layer 28T discussed above. The compositional profile of the third nonmagnetic iron-group-containing alloy layer 283 may have the characteristics of the compositional profile of the first nonmagnetic iron-group-containing alloy layer 281 discussed above.

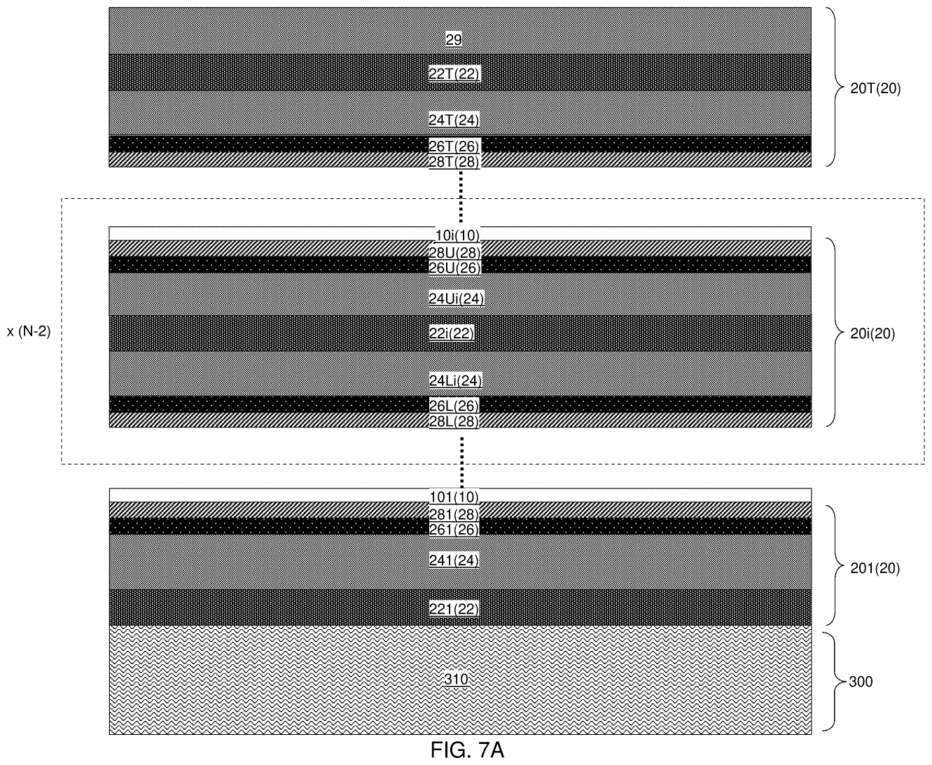

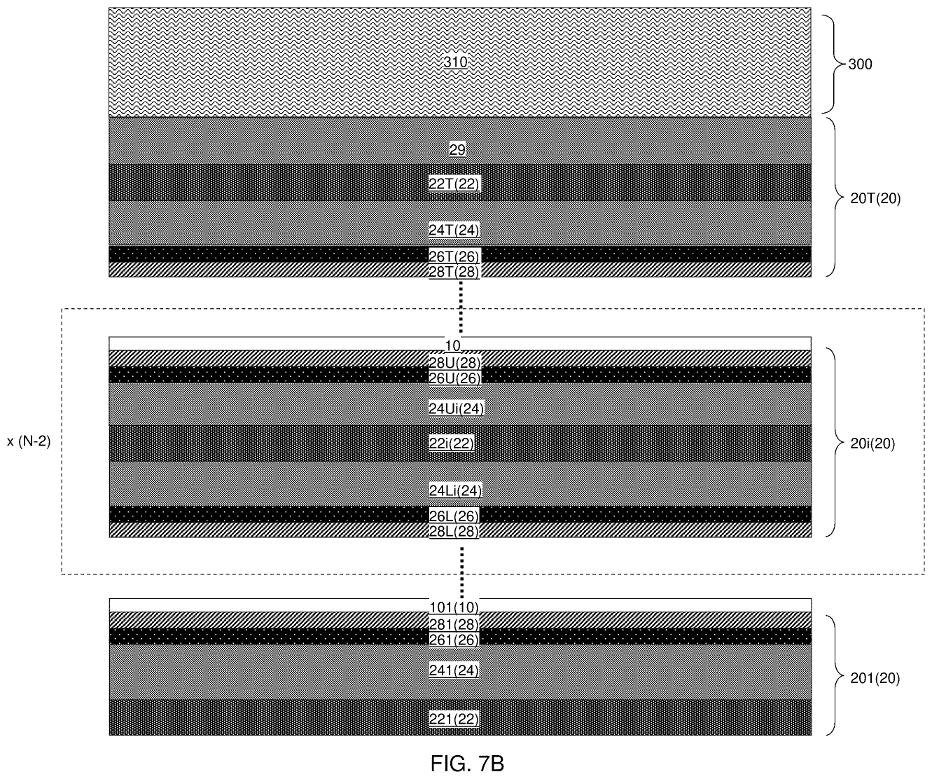

Referring to FIGS. 7A and 7B, configurations of a fourth exemplary structures according to a fourth embodiment are illustrated. The fourth exemplary structure may be derived from the third exemplary structure by inserting multiple instances of a combination of an intermediate metallic electrode 20i and an intermediate tunneling barrier dielectric layer 10i between the first tunneling barrier dielectric layer 101 and the terminal nonmagnetic iron-group-containing alloy layer 28T. Each intermediate tunneling barrier dielectric layer 10i may have any material composition that may be employed for the first tunneling barrier dielectric layer 101, and may have any thickness that may be employed for the first tunneling barrier dielectric layer 101. The material composition and/or the thickness of each intermediate tunneling barrier dielectric layer 10i may be the same as or may be different from the material composition and/or the thickness of the first tunneling barrier dielectric layer 101, respectively. The total number N of the metallic electrodes 20 may be 4 or more, such as 4 to 12.

The each intermediate metallic electrode 20i may comprise, from bottom to top, a lower nonmagnetic iron-group-containing alloy layer 28L, a lower metal layer 26L, a lower high-conductivity metallic spacer 24L, an intermediate diffusion barrier metallic spacer 22i, an upper high-conductivity metallic spacer 24U, a third metal layer 26U, and an upper nonmagnetic iron-group-containing alloy layer 28U.

Generally, the lower nonmagnetic iron-group-containing alloy layer 28L and the upper nonmagnetic iron-group-containing alloy layer 28U may independently have the same material composition and the same thickness range as any material layer that may be employed for the first nonmagnetic iron-group-containing alloy layer 281 or the terminal nonmagnetic iron-group-containing alloy layer 28T.

The lower metal layer 26L and the third metal layer 263 may independently have the same material composition and the same thickness range as any material layer that may be employed for the first metal layer 261 or the terminal metal layer 26T. The lower high-conductivity metallic spacer 24L and the upper high-conductivity metallic spacer 24U may independently have the same material composition and the same thickness range as any material layer that may be employed for the first high-conductivity metallic spacer 241 or the terminal high-conductivity metallic spacer 24T. The intermediate diffusion barrier metallic spacer 22i may have the same material composition and the same thickness range as any material layer that may be employed for the first diffusion barrier metallic spacer 221 or the terminal diffusion barrier metallic spacer 22T.

The compositional profile of the lower nonmagnetic iron-group-containing alloy layer 28L may have the characteristics of the compositional profile of the terminal nonmagnetic iron-group-containing alloy layer 28T discussed above. The compositional profile of the upper nonmagnetic iron-group-containing alloy layer 28U may have the characteristics of the compositional profile of the first nonmagnetic iron-group-containing alloy layer 281 discussed above.

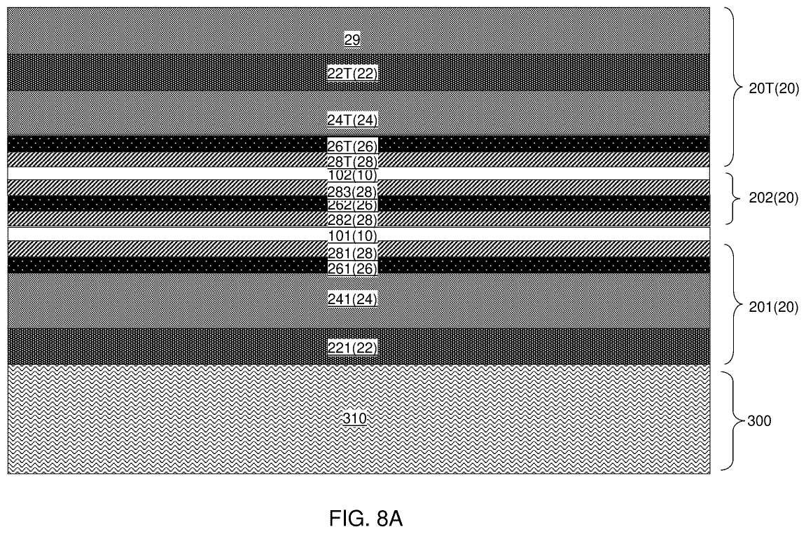

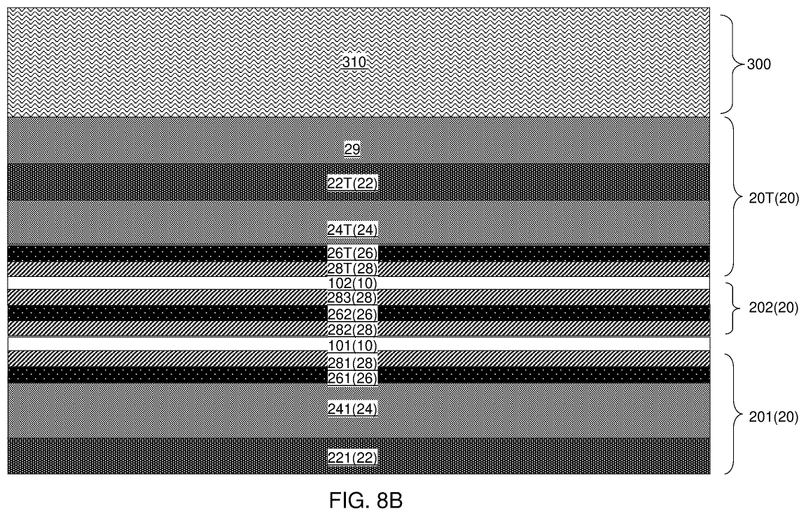

Referring to FIGS. 8A and 8B, configurations of a fifth exemplary structures according to a fifth embodiment are illustrated. The fifth exemplary structure may be derived from the third exemplary structure by omitting the second high-conductivity metallic spacer 242, the second diffusion barrier metallic spacer 222, the third high-conductivity metallic spacer 243, and the third metal layer 263 from the second metallic electrode 202. Thus, the second metallic electrode 202 may consist of, from bottom to top, a second nonmagnetic iron-group-containing alloy layer 282, a second metal layer 262, and a third nonmagnetic iron-group-containing alloy layer 283.

In this case, atoms of the transition metal element from the second metal layer 262 diffuse into the second nonmagnetic iron-group-containing alloy layer 282 and into the third nonmagnetic iron-group-containing alloy layer 283 during deposition or during an anneal to form the electrode layers 27.

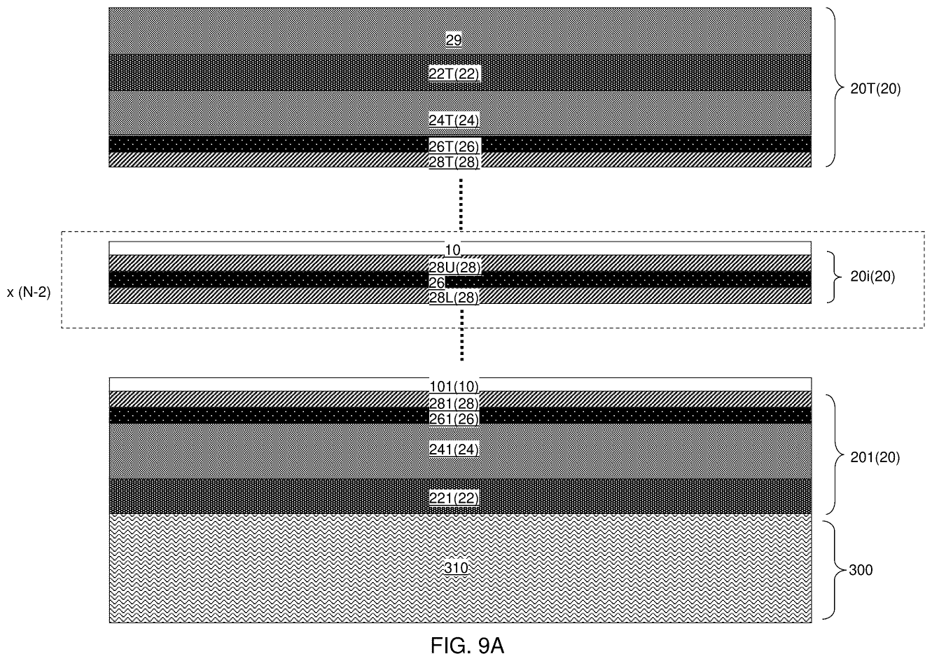

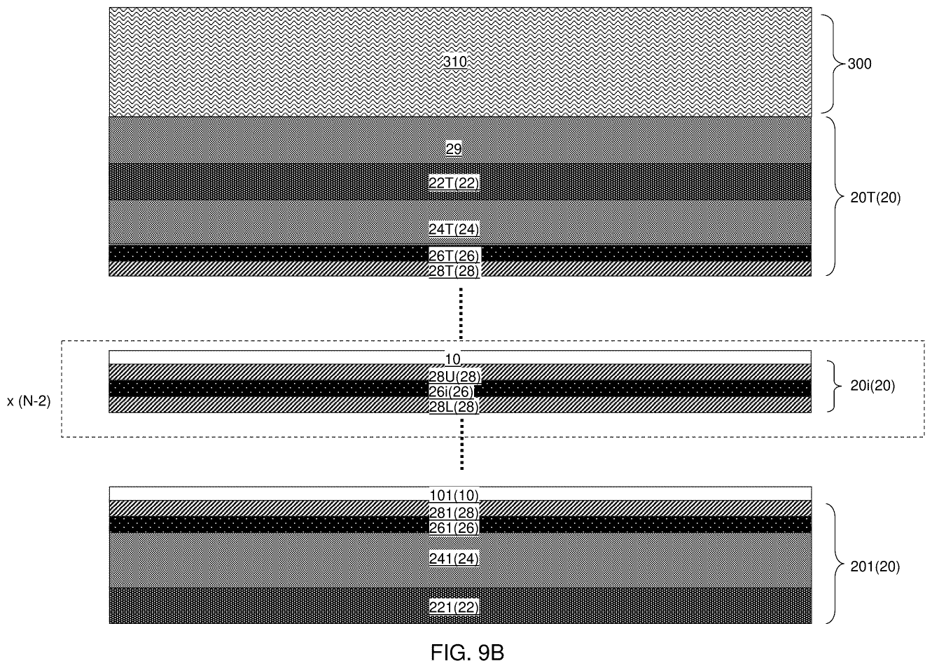

Referring to FIGS. 9A and 9B, configurations of a sixth exemplary structures according to a sixth embodiment are illustrated. The sixth exemplary structure may be derived from the fourth exemplary structure by omitting the lower high-conductivity metallic spacer 24L, the intermediate diffusion barrier metallic spacer 22i, the upper high-conductivity metallic spacer 24U, and the upper metal layer 26U from the second metallic electrode 202. Thus, each intermediate metallic electrode 20i may consist of, from bottom to top, a lower nonmagnetic iron-group-containing alloy layer 28L, an intermediate metal layer 26i (which may be the same as a lower metal layer 26L), and an upper nonmagnetic iron-group-containing alloy layer 28U.

In this case, atoms of the transition metal element from the intermediate metal layer 26i diffuse into the lower nonmagnetic iron-group-containing alloy layer 28L and into the upper nonmagnetic iron-group-containing alloy layer 28U during deposition or during an anneal to form the electrode layers 27.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device comprising a tunneling barrier resistor, wherein the tunneling barrier resistor comprises:
a first electrode layer comprising a first nonmagnetic iron-group-containing alloy layer which includes a first refractory metal;
a second electrode layer comprising a second nonmagnetic iron-group-containing alloy layer which includes a second refractory metal; and
a first tunneling barrier dielectric layer located between the first electrode layer and the second electrode layer.

2. The device of claim 1, wherein:
the first electrode comprises a first mixed metallic electrode layer comprising a first nonmagnetic iron-group-containing alloy and the first refractory metal; and
the second electrode comprises a second mixed metallic electrode layer comprising a second nonmagnetic iron-group-containing alloy and the second refractory metal.

3. The device of claim 2, wherein:
the first electrode is formed by depositing the first nonmagnetic iron-group-containing alloy layer having a thickness of 1 nm or less and a first refractory metal layer having a thickness of 1 nm or less in contact with each other; and
the second electrode is formed by depositing the second nonmagnetic iron-group-containing alloy layer having a thickness of 1 nm or less and a second refractory metal layer having a thickness of 1 nm or less in contact with each other.

4. The device of claim 3, wherein:
the first nonmagnetic iron-group-containing alloy layer is deposited as an amorphous layer;
the second nonmagnetic iron-group-containing alloy layer is deposited as an amorphous layer;
the first electrode layer comprises the mixed metallic electrode layer of a CoFe or CoFeB alloy, and the first refractory metal comprising Ta, W, Cr, Mo or Hf; and
the second electrode layer comprises the mixed metallic electrode layer of a CoFe or CoFeB alloy, and the second refractory metal comprising Ta, W, Cr, Mo or Hf.

5. The device of claim 4, wherein:
the first electrode layer comprises the mixed metallic electrode layer of the tungsten and the CoFeB alloy; and
the second electrode layer comprises the mixed metallic electrode layer of the tungsten and the CoFeB alloy.

6. The device of claim 4, wherein:
the first tunneling barrier dielectric layer thickness ranges from 0.5 nm to 1.5 nm;
the first nonmagnetic iron-group-containing alloy layer is deposited with a thickness in a range from 0.3 nm to 1 nm;
the first refractory metal layer is deposited with a thickness in a range from 0.2 nm to 1 nm that is less than the thickness of the first nonmagnetic iron-group-containing alloy layer;
the first electrode layer thickness ranges from 0.5 nm to 1.5 nm;
the second nonmagnetic iron-group-containing alloy layer is deposited with a thickness in a range from 0.3 nm to 1 nm;
the second refractory metal layer is deposited with a thickness in a range from 0.2 nm to 1 nm that is less than the thickness of the second nonmagnetic iron-group-containing alloy layer; and
the second electrode layer thickness ranges from 0.5 nm to 1.5 nm.

7. The device of claim 1, further comprising:
a third electrode layer comprising a third nonmagnetic iron-group-containing alloy layer which includes a refractory metal; and
a second tunneling barrier dielectric layer located between the third electrode layer and the second electrode layer.

8. The device of claim 1, further comprising a non-Ohmic device component that is electrically connected in series with the tunneling barrier resistor.

9. The device of claim 8, wherein the non-Ohmic device component comprises a negative differential resistance element.

10. The device of claim 9, wherein the negative differential resistance element comprises a spin torque oscillator (STO), an impact ionization avalanche transit-time (IMPATT) diode, or a Gunn diode.

11. The device of claim 9, further comprising a capacitor electrically connected in parallel with the series connection of the tunneling barrier resistor and the negative differential resistance element to a power source.

12. The device of claim 8, wherein the non-Ohmic device component comprises an ovonic threshold switch (OTS) offset voltage memory cell.

13. The device of claim 8, wherein the non-Ohmic device component comprises an ovonic threshold switch (OTS) selector of a magnetoresistive random access memory cell.

14. The device of claim 8, wherein the non-Ohmic device component comprises a resistive random access memory (ReRAM) cell.

15. A method of operating the device of claim 1, comprising passing a current through the tunneling barrier resistor using quantum tunneling.

16. A method of forming a tunneling barrier resistor, comprising:
depositing a first refractory metal layer;
depositing a first amorphous iron-group-containing alloy layer on the first refractory metal layer to form a first electrode layer comprising a first nonmagnetic iron-group-containing alloy layer which includes the first refractory metal;
depositing a first tunneling barrier dielectric layer on the first electrode layer;
depositing a second amorphous iron-group-containing alloy layer on the first tunneling barrier dielectric layer; and
depositing a second refractory metal layer on the second amorphous iron-group-containing alloy layer to form a second electrode layer comprising a second nonmagnetic iron-group-containing alloy layer which includes the second refractory metal.

17. The method of claim 16, wherein:
the first electrode comprises a first mixed metallic electrode layer comprising a first nonmagnetic iron-group-containing alloy and the refractory metal; and
the second electrode comprises a second mixed metallic electrode layer comprising a second nonmagnetic iron-group-containing alloy and the refractory metal.

18. The method of claim 17, wherein:
the first electrode layer comprises the mixed metallic electrode layer of a CoFe or CoFeB alloy, and the first refractory metal comprising Ta, W, Cr, Mo or Hf; and
the second electrode layer comprises the mixed metallic electrode layer of a CoFe or CoFeB alloy, and the second refractory metal comprising Ta, W, Cr, Mo or Hf.

19. The method of claim 18, wherein:
the first electrode layer comprises the mixed metallic electrode layer of the tungsten and the CoFeB alloy;
the second electrode layer comprises the mixed metallic electrode layer of the tungsten and the CoFeB alloy;
the first tunneling barrier dielectric layer thickness ranges from 0.5 nm to 1.5 nm;
the first nonmagnetic iron-group-containing alloy layer is deposited with a thickness in a range from 0.3 nm to 1 nm;
the first refractory metal layer is deposited with a thickness in a range from 0.2 nm to 1 nm, which is less than the thickness of the first nonmagnetic iron-group-containing alloy layer;
the first electrode layer thickness ranges from 0.5 nm to 1.5 nm;
the second nonmagnetic iron-group-containing alloy layer is deposited with a thickness in a range from 0.3 nm to 1 nm;
the second refractory metal layer is deposited with a thickness in a range from 0.2 nm to 1 nm, which is less than the thickness of the second nonmagnetic iron-group-containing alloy layer; and
the second electrode layer thickness ranges from 0.5 nm to 1.5 nm.

20. The method of claim 16, further comprising forming a negative differential resistance element in series with the tunneling barrier resistor.
